(19) United States
(12) Patent Application Publication
(10) Pub. No.: US 2026/0288042 A1
(43) Pub. Date: Sep. 24, 2026

(54) IMAGE FORMING APPARATUS

(71) Applicant: Tomohide KONDO, Kanagawa (JP)

(72) Inventor: Tomohide KONDO, Kanagawa (JP)

(21) Appl. No.: 19/561,525

(22) Filed: Mar. 10, 2026

(30) Foreign Application Priority Data
Mar. 18, 2025 (JP) 2025-044015

(51) Int. Cl. G03G 15/00; G01R 19/00; G03G 15/08; G06K 15/00

(52) U.S. Cl. CPC G03G 15/556; G01R 19/0092; G03G 15/0856; G03G 15/0872; G03G 15/5016; G06K 15/005; G06K 15/4075; G06K 15/408

(57) ABSTRACT

An image forming apparatus includes a toner container, a rotation motor, a detector, a display, and circuitry. The toner container stores toner used for image formation. The rotation motor rotates the toner container. The detector detects a drive current. The display displays a stored state of the toner in the toner container. The circuitry controls the rotation motor to rotate the toner container, aquire the drive current detected by the detector while rotating the toner container, determines whether the drive current has a pulsating current waveform based on the drive current, determines that the stored state of the toner is in an abnormal state when the drive current has the pulsating current waveform, and controls the display to display that the stored state is in the abnormal state in response to a determination of the stored state in the abnormal state when the drive current has the pulsating current waveform.

### CROSS-REFERENCE TO RELATED APPLICATION

This patent application is based on and claims priority pursuant to 35 U.S.C. § 119(a) to Japanese Patent Application No. 2025-044015, filed on Mar. 18, 2025, in the Japan Patent Office, the entire disclosure of which is hereby incorporated by reference herein.

### BACKGROUND

### Technical Field

The present disclosure relates to an image forming apparatus.

### Related Art

An image forming apparatus is known that transfers an image developed using a developing material such as toner onto a medium. The image forming apparatus includes a mechanism that rotates a toner bottle containing toner therein by a motor and discharges and supplies the toner in the toner bottle to a developing device.

### SUMMARY

The present disclosure described herein provides an image forming apparatus that includes a toner container, a rotation motor, a detector, a display, and circuitry. The toner container stores toner used for image formation. The rotation motor driven by a drive current rotates the toner container. The detector detects the drive current. The display displays a stored state of the toner in the toner container. The circuitry controls the rotation motor to rotate the toner container, aquire the drive current detected by the detector while rotating the toner container by the rotation motor, determines whether the drive current has a pulsating current waveform based on the drive current detected by the detector, determines that the stored state of the toner is in an abnormal state when the drive current has the pulsating current waveform, and controls the display to display that the stored state is in the abnormal state in response to a determination of the stored state in the abnormal state when the drive current has the pulsating current waveform.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a diagram illustrating a hardware configuration of an image forming apparatus according to an embodiment of the present disclosure;

FIG. 2 is a diagram illustrating a configuration of a toner supply mechanism;

FIG. 3 is a diagram illustrating an example of a motor current of a toner container rotation motor;

FIG. 4 is a diagram illustrating another example of a motor current of a toner container rotation motor; and

FIG. 5 is a flowchart of an example of a toner adhesion determination control process.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. Identical reference numerals are assigned to identical or equivalent components and a description of those components may be simplified or omitted. As used herein, the singular forms “a,” “an,” and “the” are intended to include the plural forms as well, unless the context clearly indicates otherwise.

The image forming apparatus according to the present disclosure performs an image forming process by a so-called electrophotographic method. The basic configuration is the similar to that of a comparative example, so a detailed description thereof is omitted. Then, a description is given of its characteristic configuration of the present disclosure.

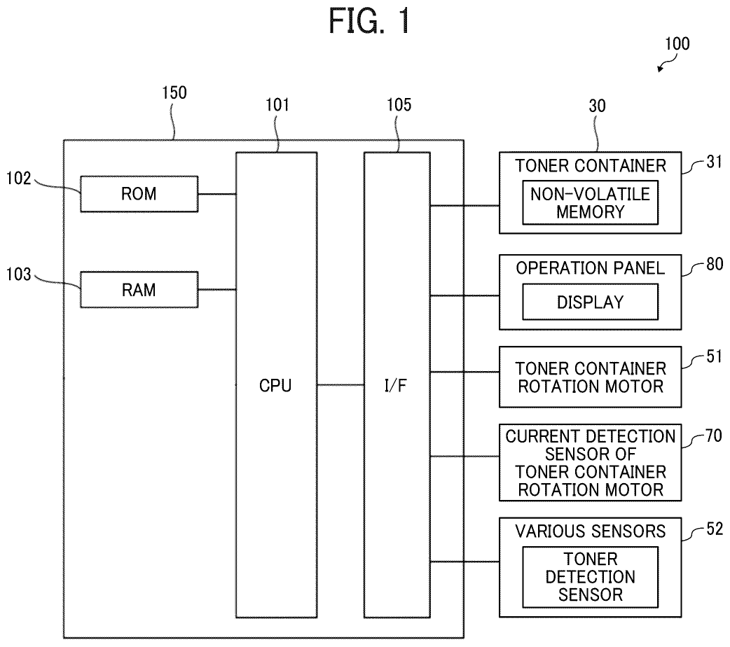

FIG. 1 is a diagram illustrating a hardware configuration of a control configuration of an image forming apparatus 100 according to the present embodiment. As illustrated in FIG. 1, a controller 150 according to the present embodiment includes a central processing unit (CPU) 101, a read-only memory (ROM) 102, a random-access memory (RAM) 103, and an input-and-output interface (I/F) 105.

The CPU 101 reads out a program or date from a storage device such as the ROM 102 or a hard disc drive (HDD) 104 onto the RAM 103, and executes a specified process defined by the program, so that the CPU 101 controls the entire image forming apparatus 100. The CPU 101 is connected to a nonvolatile memory 31 attached to a toner container 30, a display 80 of an operation panel, a toner-container rotation motor 51, a toner-container-rotation-motor current detector 70 as a motor current detector, and a toner detection sensor 52 via the input-and-output I/F 105 to communicate with each other. The CPU 101 performs a specified operation in accordance with various signals (date) input from above-described devices, and outputs a control signal.

The nonvolatile memory 31 attached to the toner container 30 stores information to enable identifying the toner container 30. For example, the information on the characteristics (e.g., colors) of the toner stored in the toner container 30 is stored. The information is made readable when the toner container 30 is attached to the image forming apparatus 100.

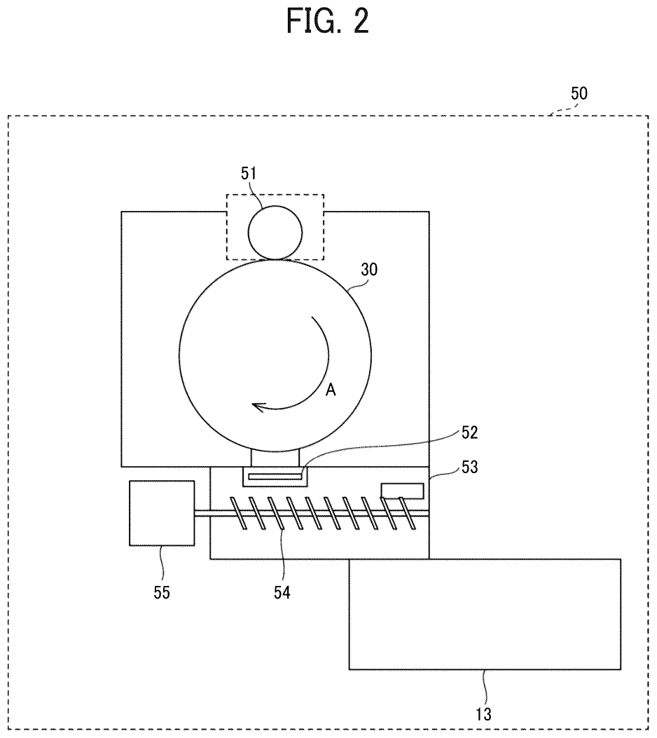

The display 80 constitutes the operation panel included in the image forming apparatus 100, includes a touch interface, and functions as a user interface for a user to input an instruction to the image forming apparatus 100. The display 80 also has a function of displaying a notification to notify a user of an operation state of the image forming apparatus 100. The display 80 also displays a message prompting a user to remove or replace the toner container 30 (see FIG. 2) of the image forming apparatus 100 under the control of the controller 150.

The toner-container rotation motor 51 operates to supply toner to a developing unit 13 (see FIG. 2) while agitating toner contained in the toner container 30 attached to the image forming apparatus 100. The toner-container rotation motor 51 rotates the toner container 30 at a specified time interval and a specified rotation speed under the control of the controller 150. In the present embodiment, the toner-container rotation motor 51 is, for example, a motor with a brush, but is not limited thereto. As described later, the present embodiment is applicable to any case where the drive current periodically varies in a situation where the rotation is not uniform due to the internal state of the toner container 30.

The toner-container-rotation-motor current detector 70 detects a motor current (drive current) for rotating the toner-container rotation motor 51. The CPU 101 receives the motor current detected by the toner-container-rotation-motor current detector 70, and controls the operation current to the toner-container rotation motor 51.

The toner detection sensor 52 detects information that varies depending on the remaining amount of toner in the toner container 30. The detection result of the toner detection sensor 52 is notified to the CPU 101, so that the remaining amount of toner is detected by the execution of the program in the CPU 101.

Next, with reference to FIG. 2, a description is given of a toner supply mechanism 50 according to the present embodiment in detail. FIG. 2 is a schematic view illustrating an example of the configuration of the toner supply mechanism 50. The toner supply mechanism 50 is a mechanism section that is disposed on the back side of a toner container storage included in the image forming apparatus 100 (inside a body of the image forming apparatus), is stored in the toner container storage, and supplies toner to the developing unit 13 from the toner container 30 that is a cylindrical bottle for storing the toner.

The toner supply mechanism 50 includes the toner-container rotation motor 51 that rotates the toner container 30, the toner detection sensor 52 that detects toner discharged from the toner container 30, a toner conveyance passage 53, a screw 54, and a screw drive motor 55.

The toner container 30 has a groove that engages with a gear train of the toner-container rotation motor 51 on its side circumferential surface. Accordingly, the toner container 30 rotates (for example, rotates in the direction indicated by the arrow A in FIG. 2) in accordance with the rotation of the toner-container rotation motor 51. Toner is discharged to the toner conveyance passage 53 disposed outside the toner container 30 by the rotation of the toner container 30.

Although not particularly limited, the toner detection sensor 52 of the present embodiment is a piezoelectric sensor disposed in the toner conveyance passage 53. Toner discharged from the toner container 30 falls and contacts the toner detection sensor 52, so that the toner detection sensor 52 detects the toner in the toner container 30. The toner detection sensor 52 outputs a toner detection signal to the controller 150.

The screw 54 rotated by the screw drive motor 55 conveys toner discharged from the toner container 30 toward the developing unit 13. As a result, the toner supply mechanism 50 supplies the toner to the developing unit 13.

The toner is formed of minute particles. When the toner is left inside the toner container 30, the toner remains in the gravity direction. The toner moves on the inner wall of the toner container 30 in a direction different from the gravity direction with the rotation of the toner container 30. However, when the toner moves to a certain position, the toner falls by gravity. As described above, in the normal state, the toner has fluidity inside the toner container 30 in accordance with the rotation of the toner container 30.

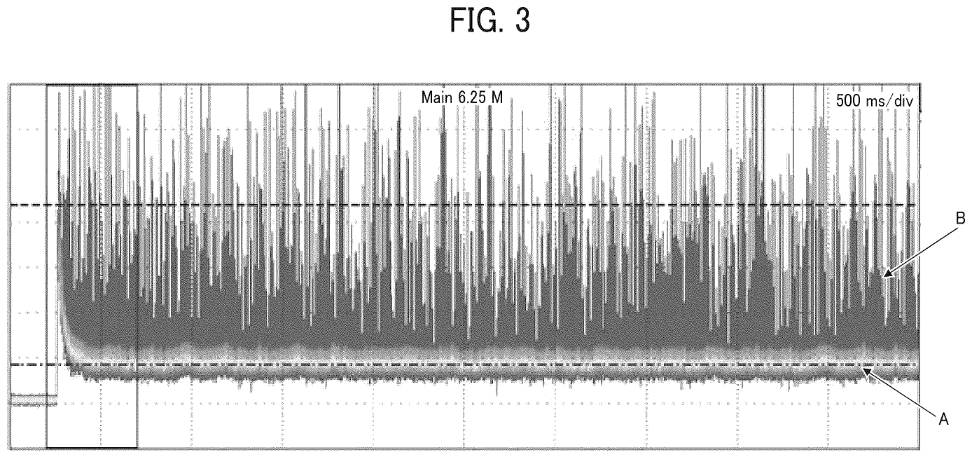

Next, a description is given of a current waveform of the toner-container rotation motor 51 according to the present embodiment. FIG. 3 illustrates an example of a waveform of a motor current in a state where the toner held in the toner container 30 is not fixed inside the toner container 30 and is flowing and being stirred inside the toner container 30 with rotation as described above. In other words, an example of the waveform of the motor current in FIG. 3 illustrates the current waveform of the toner-container rotation motor 51 in a case where the toner is not fixed inside the toner container 30 and the toner container 30 is in a normal state.

In a case where the toner-container rotation motor 51 is a motor with a brush, for example, when the toner container 30 is rotated at a constant speed by the toner-container rotation motor 51 in a state where the fluidity of the toner in the toner container 30 is kept normal, the motor current waveform of the toner-container rotation motor 51 becomes a normal current waveform A. In other words, in a state where the fluidity of the toner is kept normal, the motor current is stable at a specified value. FIG. 3 illustrates an example in which the toner-container rotation motor 51 is a motor with a brush, so that the spark noise B due to friction between the brush and the commutator appears.

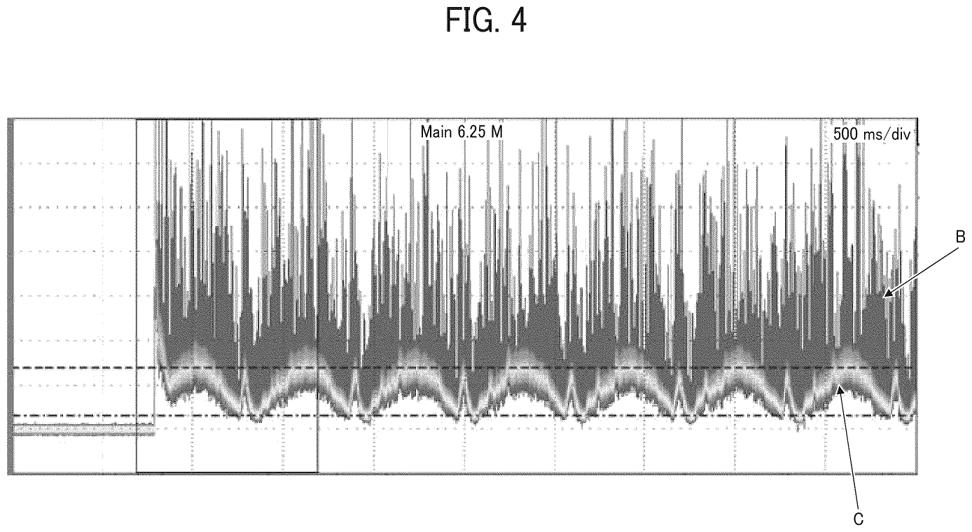

FIG. 4 illustrates an example in which a motor with a brush is used as the toner-container rotation motor 51, and illustrates the motor current in a state where toner in the toner container 30 is fixed and loses fluidity, as in the case of FIG. 3. When the toner container 30 is rotated while the toner is fixed inside the toner container 30, the center of gravity during rotation is greatly biased. Thus, even if the toner-container rotation motor 51 attempts to rotate at a constant speed, the rotation speed of the toner container 30 periodically fluctuates. Under the influence of the periodic fluctuation of the rotational speed, the waveform of the motor current also periodically fluctuates.

In the present embodiment, the motor current that periodically fluctuates as illustrated in FIG. 4 is referred to as a “pulsating current”.

In other words, when toner in the toner container 30 is fixed, the toner does not move from a part of the toner container 30 (a specific position inside the toner container 30), and the toner is unevenly distributed on a part of the inner wall of the toner container 30. In this case, the load on the toner-container rotation motor 51 due to the rotation of the toner container 30 is not constant, and periodically fluctuates. As a result, the motor current of the toner-container rotation motor 51 becomes a pulsating current that fluctuates in accordance with the rotation cycle of the toner container 30.

In other words, when the toner container 30 is in an abnormal state in which the toner is fixed and loses fluidity, the current waveform of the toner-container rotation motor 51 becomes a waveform of a pulsating current (pulsating current waveform C) that fluctuates at a constant period in accordance with the rotation period of the toner container 30. FIG. 4 illustrates an example in which the toner-container rotation motor 51 is a motor with a brush, and thus, spark noise B due to friction between the brush and the commutator appears.

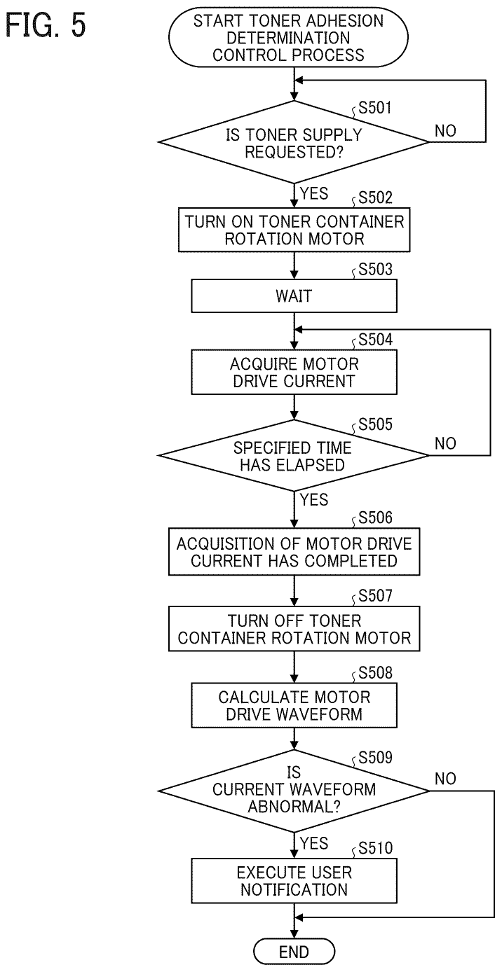

Next, a description is given of a flow of a tone-adhesion determination control process based on the premise that the pulsating current waveform C is generated when the toner is fixed inside the toner container 30 as illustrated in FIG. 4 with reference to the flowchart of FIG. 5.

First, the process is looped and waits until the controller 150 requests the developing unit 13 to supply toner (NO in step S501 of FIG. 5). When the controller 150 requests the developing unit 13 to supply the toner (YES in step S501 of FIG. 5), the toner-container rotation motor 51 is rotated (in step S502 of FIG. 5) to start supplying toner from the toner container 30 to the developing unit 13.

Next, after the period in which the starting current flows at the start of rotation of the toner-container rotation motor 51 has elapsed (in step S503 of FIG. 5), the motor current of the toner-container rotation motor 51 is acquired using the toner-container-rotation-motor current detector 70 (in step S504 of FIG. 5). In order to continue step S504 for a specified time, the lapse of the specified time is monitored (in step S505 of FIG. 5). The process loops until the process of rotating the toner-container rotation motor 51 and acquiring the toner current is continued for a specified time (NO in step S505 of FIG. 5). When a specified time has elapsed (YES in step S505 of FIG. 5), the acquisition of the motor current of the toner-container rotation motor 51 is ended (in step S506 of FIG. 5). In step S506, the motor current of the toner-container rotation motor 51 acquired during a specified time is stored in the RAM 103.

Next, when the time for completing the toner supply according to the amount of the toner supply request has elapsed after the rotation of the toner-container rotation motor 51 is started in step S502 of FIG. 5, the toner-container rotation motor 51 is stopped (in step S507 of FIG. 5), and then the toner supply is ended.

Subsequently, a low-pass filter operation is performed on the motor current value of the toner-container rotation motor 51 stored in the RAM 103 by the arithmetic processing by the CPU 101 in step S506, and then the current waveform from which the noise current is removed is calculated (in step S508 of FIG. 5).

Regarding the current waveform calculated in step S508, the CPU 101 determines whether the current waveform is a normal current waveform A, which is a waveform of the motor current in a normal state, or a pulsating current waveform C, which is a waveform of an abnormal current (in step S509 of FIG. 5). When the calculated current waveform is the pulsating current waveform C (YES in step S509 of FIG. 5), the toner is fixed inside the toner container 30, so that the CPU 101 executes a user notification process for performing the display information instruction to the display 80 (in step S510 of FIG. 5) in order to display on the display 80 a message for prompting a user to take an appropriate action. Such a configuration prevents the quality of the formed image from being impaired when a user takes out the toner container 30, stirs toner, and returns the toner container 30 to the image forming apparatus 100 to resume the image forming process in the case where the toner supply becomes abnormal. Further, such a configuration effectively prompts a user to replace the toner container 30 at an appropriate time.

In step S509 of FIG. 5, when the current waveform is the normal current waveform A (NO in step S509 of FIG. 5), the process is ended without notifying a user.

In the user notifying process in step S510, the controller 150 causes the display 80 to display a message indicating that toner is in an abnormal condition. In addition, in step S510 of FIG. 5, the controller 150 causes the display 80 to display a message indicating that the toner is in an abnormal condition and a message prompting a user to replace the toner containers 30.

In step S510, the controller 150 causes the display 80 to display a message indicating that toner is in an abnormal condition and a message prompting a user to temporarily remove and set the toner containers 30. When the pulsating current waveform C is detected again after a user has taken out the toner container 30 and set it again, the controller 150 causes the display 80 to display a message prompting the user to replace the toner container 30.

In step S510, the controller 150 causes the display 80 to display that toner is in an abnormal condition, and to prompt the user to take out the toner container 30 once and set it. After a user has once taken out the toner container 30 and reset it, when the pulsating current waveform C is detected again, the controller 150 causes the display 80 to display a message notifying a service call. The service call is a process of notifying a maintenance person of the image forming apparatus 100 of an abnormal state of the toner container 30.

According to the present embodiment described above, the controller 150 detects the motor current of the toner-container rotation motor 51 that rotates the toner container 30, and detects whether the motor current of the toner-container rotation motor 51 pulsates in accordance with the rotation cycle of the toner container 30. When the motor current is pulsating, the controller 150 determines that the toner is fixed at a part of the positions inside the toner container 30.

An image forming apparatus includes a toner container, a rotation motor, a detector, a display, and circuitry. The toner container stores toner used for image formation. The rotation motor driven by a drive current rotates the toner container. The detector detects the drive current. The display displays a stored state of the toner in the toner container. The circuitry controls the rotation motor to rotate the toner container, aquire the drive current detected by the detector while rotating the toner container by the rotation motor, determines whether the drive current has a pulsating current waveform based on the drive current detected by the detector, determines that the stored state of the toner is in an abnormal state when the drive current has the pulsating current waveform, and controls the display to display that the stored state is in the abnormal state in response to a determination of the stored state in the abnormal state when the drive current has the pulsating current waveform.

The circuitry further controls the display to display a notification prompting replacement of the toner container in response to the determination of the stored state in the abnormal state.

The circuitry further controls the display to display that the stored state is in the abnormal state in response to the determination of the stored state in the abnormal state, to display a notification prompting a temporary removal and resetting of the toner container in response to the determination of the stored state in the abnormal state, to redetermine whether the stored state is in the abnormal state after the temporary removal and resetting of the toner container, and to display a notification prompting replacement of the toner container in response to a redetermination of the stored state in the abnormal state.

The circuitry further controls the display to display that the stored state is in the abnormal state in response to the determination of the stored state in the abnormal state, to display a notification prompting a temporary removal and resetting of the toner container in response to the determination of the stored state in the abnormal state, to redetermine whether the stored state is in the abnormal state after the temporary removal and resetting of the toner container, and to display a notification of a request of a service call in response to a redetermination of the stored state in the abnormal state.

Embodiments of the present disclosure are not limited to the above-described embodiments and modifications, and numerous additional modifications and variations are possible in light of the teachings. The technical contents included in the technical ideas described in the appended claims are included within the technical scope of the appended claims. The above-described embodiments and modifications are some examples, and various modifications and variations can be practiced from such examples by those skilled in the art. Such modifications and variations are included in the technical scope described in the appended claims.

Aspects of the present disclosure are, for example, as follows.

### First Aspect

An image forming apparatus (e.g., the image forming apparatus 100) includes a toner container (e.g., the toner container 30), a rotation motor (e.g., the rotation motor 51), a motor current detector (e.g., the toner-container-rotation-motor current detector 70), a display (e.g., the display 80) that displays a display corresponding to a rotation state of the rotation motor, and a controller (e.g., the controller 150). The toner container holds toner used for image formation. The rotation motor rotates the toner container. The motor current detector detects a drive current of the rotation motor. The controller controls an operation of the rotation motor. When the drive current is a pulsating current, the controller determines that a toner holding state inside the toner container is in an abnormal state, and causes a display (e.g., the display 80) to display that the toner is in the abnormal state.

### Second Aspect

In the image forming apparatus (e.g., the image forming apparatus 100) according to the first aspect, when the controller (e.g., the controller 150) determines that the toner holding state is in the abnormal state, the controller causes the display (e.g., the display 80) to display that the toner is abnormal and to display that a user is prompted to replace the toner container (e.g., the toner container 30).

### Third Aspect

In the image forming apparatus (e.g., the image forming apparatus 100) according to the first or second aspect, when the controller (e.g., the controller 150) determines that the toner holding state is abnormal, the controller (e.g., the controller 150) causes the display (e.g., the display 80) to display that the toner is abnormal and causes the display to display that a user is prompted to set the toner container (e.g., the toner container 30) again after the toner container is once taken out. After that, when the controller determines that the toner holding state is abnormal again, the controller causes the display to display that the toner container is prompted to be replaced.

### Fourth Aspect

In the image forming apparatus (e.g., the image forming apparatus 100) according to any one of the first to third aspect, when the controller (e.g., the controller 150) determines that the toner holding state is abnormal, a user temporarily takes out the toner container (e.g., the toner container 30) and sets the toner container again. After that, when the controller determines that the toner holding state is abnormal again, the controller notifies the display (e.g., the display 80) of a service call.

The above-described embodiments are illustrative and do not limit the present disclosure. Thus, numerous additional modifications and variations are possible in light of the above teachings. For example, elements and/or features of different illustrative embodiments may be combined with each other and/or substituted for each other within the scope of the present disclosure. Any one of the above-described operations may be performed in various other ways, for example, in an order different from the one described above.

The functionality of the elements disclosed herein may be implemented using circuitry or processing circuitry which includes general purpose processors, special purpose processors, integrated circuits, application-specific integrated circuits (ASICs), field-programmable gate arrays (FPGAs), and/or combinations thereof which are configured or programmed, using one or more programs stored in one or more memories, to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of an FPGA or ASIC.

1. An image forming apparatus comprising:
a toner container storing toner used for image formation;
a rotation motor, driven by a drive current, to rotate the toner container;
a detector to detect the drive current;
a display to display a stored state of the toner in the toner container; and
circuitry configured to:
control the rotation motor to rotate the toner container;
aquire the drive current detected by the detector while rotating the toner container by the rotation motor;
determine whether the drive current has a pulsating current waveform based on the drive current detected by the detector;
determine that the stored state of the toner is in an abnormal state when the drive current has the pulsating current waveform; and
control the display to display that the stored state is in the abnormal state in response to a determination of the stored state in the abnormal state when the drive current has the pulsating current waveform.

2. The image forming apparatus according to claim 1,
wherein the circuitry is further configured to control the display to display a notification prompting replacement of the toner container in response to the determination of the stored state in the abnormal state.

3. The image forming apparatus according to claim 1,
wherein the circuitry is further configured to control the display to:
display that the stored state is in the abnormal state in response to the determination of the stored state in the abnormal state;
display a notification prompting a temporary removal and resetting of the toner container in response to the determination of the stored state in the abnormal state;
redetermine whether the stored state is in the abnormal state after the temporary removal and resetting of the toner container; and
display a notification prompting replacement of the toner container in response to a redetermination of the stored state in the abnormal state.

4. The image forming apparatus according to claim 1,
wherein the circuitry is further configured to control the display to:
display that the stored state is in the abnormal state in response to the determination of the stored state in the abnormal state;
display a notification prompting a temporary removal and resetting of the toner container in response to the determination of the stored state in the abnormal state;
redetermine whether the stored state is in the abnormal state after the temporary removal and resetting of the toner container; and
display a notification of a request of a service call in response to a redetermination of the stored state in the abnormal state.
